(19) United States
(12) Patent Application Publication
(10) Pub. No.: US 2005/0260776 A1
(43) Pub. Date: Nov. 24, 2005

(54) Structure and method for extraction of parasitic junction capacitance in deep submicron technology

(75) Inventors: Yin-Pin Wang, Kaohsiung City (TW); Huan-Tsung Huang, Hsinchu City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/848,887

(22) Filed: May 19, 2004

(51) Int. Cl. H01L 21/66; H01L 21/336; H01L 21/8234

(52) U.S. Cl. 438/14; 438/17; 438/197; 438/279

(57) ABSTRACT

The present disclosure provides a structure and method for determining a parasitic junction voltage that cannot be directly measured because of lack of space for a probe. For example, the method may be used with a test structure having at least two transistors pairs. The first transistor pair may include a shared source or drain associated with a parasitic junction capacitance (Csb1), and two gates spaced to enable direct measurement of Csb1. The second transistor pair may include a shared source or drain associated with a parasitic junction capacitance (Csb2), and two gates spaced to prevent direct measurement of Csb2. The method may involve measuring a first total junction capacitance (C1) of the first transistor pair, measuring Csb1, measuring a second total junction capacitance (C2) of the second transistor pair, and determining Csb2 using C1, C2, and Csb1.

### BACKGROUND

The present disclosure relates generally to the field of semiconductor integrated circuits and, more particularly, to a structure and method for determining parasitic junction capacitance in deep submicron technology.

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing have been needed.

In the course of integrated circuit evolution, functional density (i.e., the number of interconnected devices per chip area) has generally increased while feature size (i.e., the smallest component (or line) that can be created using a fabrication process) has decreased. This scaling down process generally provides benefits by increasing production efficiency and lowering associated costs. However, such scaling down also introduces physical limitations related to accessing the device when testing capacitances and other device characteristics.

Accordingly, what is needed is a design structure and method for determining semiconductor device characteristics for areas that cannot be directly accessed for measurements.

### BRIEF DESCRIPTION OF THE DRAWINGS

FIG. 1 is a top view of one embodiment of a test structure that enables a capacitance to be calculated for an area with which direct contact is not feasible.

FIG. 2 is a top view of one portion of the semiconductor structure of FIG. 1 having two transistors connected in series with a shared source that may be accessed directly.

FIG. 3 is a cross sectional view of the portion of the semiconductor structure of FIG. 2.

FIG. 4 is a top view of another portion of the semiconductor structure of FIG. 1 having two transistors connected in series with a shared source that may not be accessed directly.

FIG. 5 is a cross-sectional view of the portion of the semiconductor structure of FIG. 4.

FIG. 6 is a flow chart of an exemplary method for determining parasitic junction capacitance in the portion of FIG. 4 using the structure of FIG. 1.

FIGS. 7a and 7b are cross sectional views of the portion illustrated in FIG. 3 with respect to the method of FIG. 6.

FIGS. 7c and 7d are cross sectional views of the portion illustrated in FIG. 5 with respect to the method of FIG. 6.

### DETAILED DESCRIPTION

The present disclosure relates generally to the field of semiconductor integrated circuits and, more particularly, to a structure and method for determining parasitic junction capacitance. It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

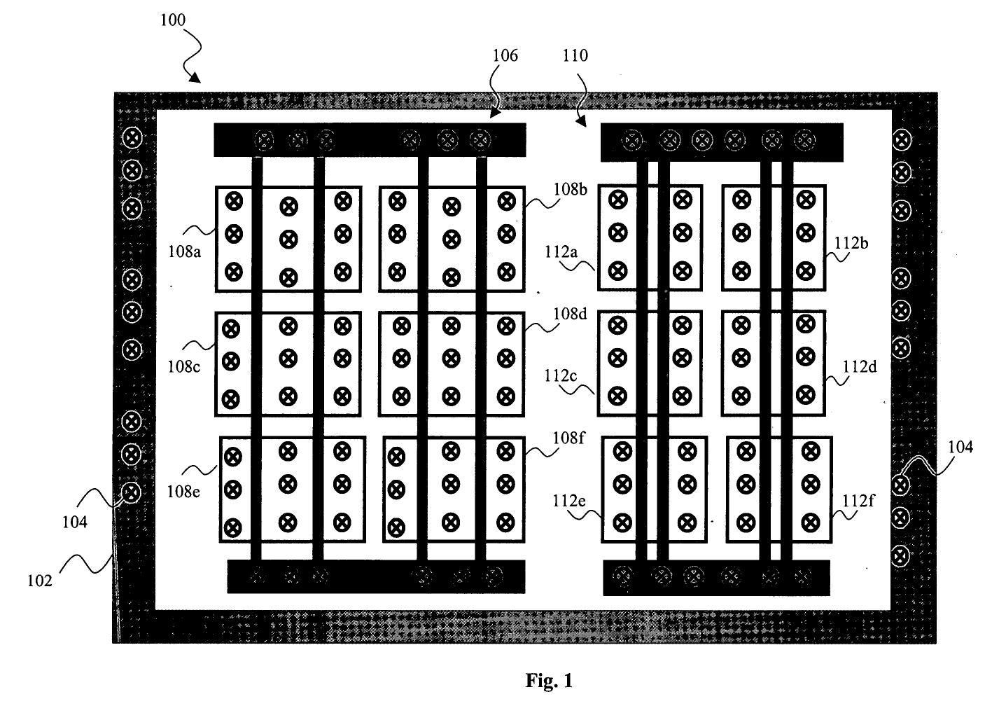

Referring to FIG. 1, in one embodiment, a test structure 100 comprises a substrate region 102 that may include a plurality of substrate contacts 104, a structure 106 (also referred to as ‘A’), and a structure 110 (also referred to as ‘B’). As will be described later in greater detail, the structures 106, 110 enable the measurement of parasitic junction capacitance when such measurements may not be made directly due to the lack of room for a probe or other measuring device. The structure 106 includes an array of metal oxide semiconductor (MOS) transistors, where the space between the gates of the transistors is large enough for a probe to make contact between the gates. In the present example, the structure 106 includes active regions 108a-108f (a total of six active regions), with each active region having two MOS transistors connected in series. The structure 110 includes an array of MOS transistors, where the space between the gates is too small for a probe to make contact between the gates. As with the structure 106, in the present example, the structure 110 includes active regions 112a-112f (a total of six active regions), with each active region having two MOS transistors connected in series.

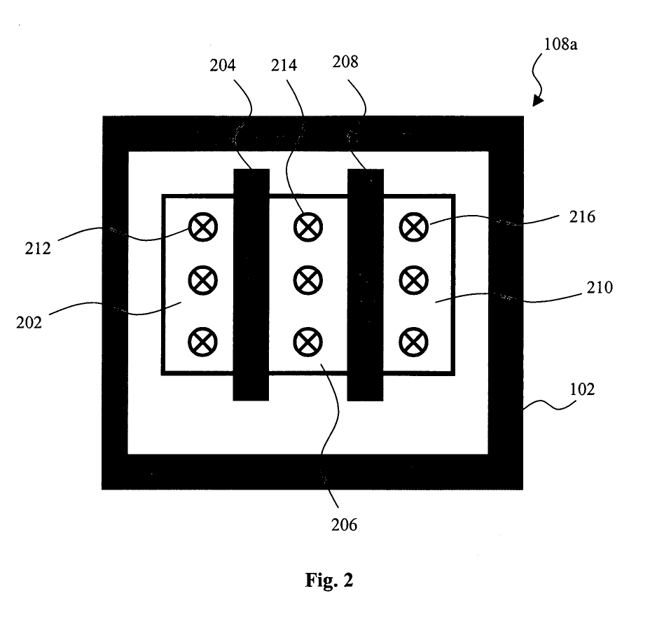

With additional reference to FIG. 2, the active region 108a is illustrated in greater detail. The active region 108a comprises two MOS field effect transistors (MOSFETs) that are connected in series. The MOSFETs may be n-channel (NMOS) or p-channel (PMOS) transistors. To provide the two MOSFETS, the active region 108a includes a drain 202, a gate 204, and a source 206 for the first MOS, and the source 206 (which is a shared source for both MOSFETs), a gate 208, and a drain 210 for the second MOS. The MOSFETs also include contacts 212 for the drain 202, contacts 214 for the shared source 206, and contacts 216 for the drain 210. It is understood that gates 204, 208 may also be associated with contacts, but are illustrated without contacts for purposes of clarity. Accordingly, references to the gates 204, 208 may also be references to contacts associated with the gates. Because the illustrated configuration of the active region 108a provides sufficient space between the gates 204, 208 for the contacts 214, the parasitic junction capacitance at the source 206 may be directly measured.

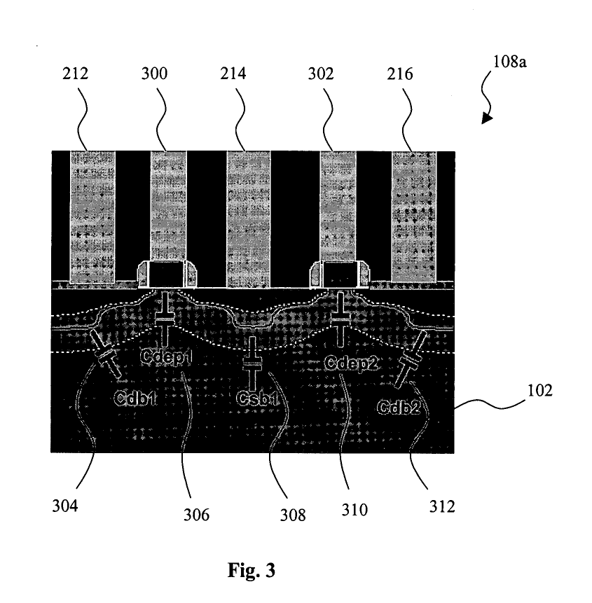

With additional reference to FIG. 3, the active region 108a of FIGS. 1 and 2 is illustrated with contacts 212, 214, 216, 300, and 302, as well as various parasitic junction capacitances 304, 306, 308, 310, and 312. The contacts provide connections to various components of the active region 108a as follows. The contact 212 is connected to the drain 202, the contact 300 is connected to the gate 204, the contact 214 is connected to the shared source 206, the contact 302 is connected to the gate 208, and the contact 216 is connected to the drain 210.

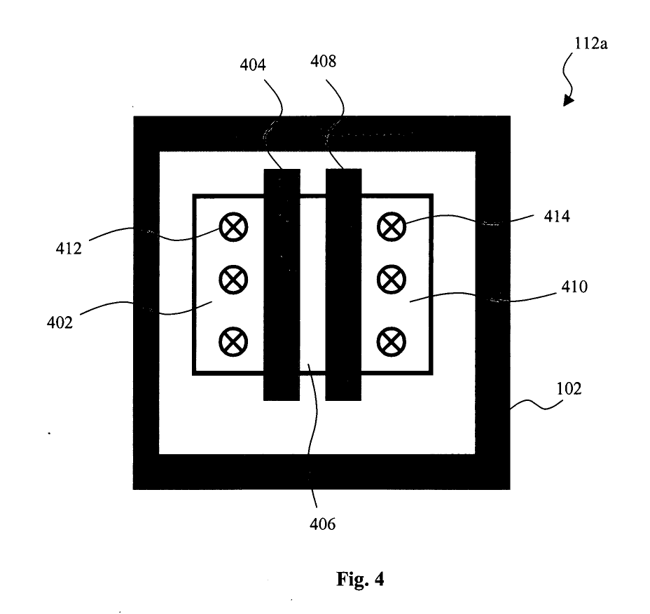

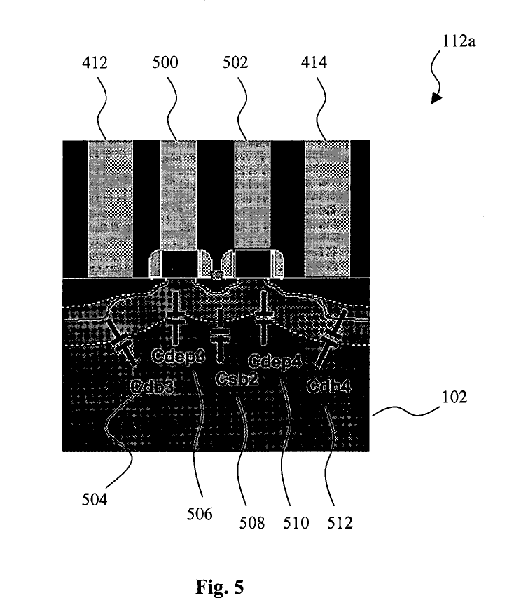

The parasitic junction capacitances include the parasitic junction capacitance 304 (e.g., Cdb1) between the drain 202 and substrate 102, the parasitic junction capacitance 306 (e.g., Cdep1) between the gate 204 and substrate 102, the parasitic junction capacitance 308 (e.g., Csb1) between the source 206 and substrate 102, the parasitic junction capacitance 310 (e.g., Cdep2) between the gate 208 and substrate 102, and the parasitic junction capacitance 312 (e.g., Cdb2) between the drain 210 and substrate 102. Such capacitances are generally a considered factor in transistor design simulation, and may be used as parameters that may be monitored during manufacturing. As the feature size of transistors produced during fabrication is scaled down to the deep submicron level, it becomes more difficult to directly measure capacitances, including the parasitic junction capacitances. For example, while each of the parasitic junction capacitances 304, 306, 308, 310, and 312 may be measured directly in the configuration of the active region 108a, the space between the polycrystalline silicon gates 204, 208 may be scaled down until there is not enough room for a probe to make contact as needed to directly measure the various capacitances (FIGS. 4 and 5).

With additional reference to FIG. 4, the active region 112a of FIG. 1 is illustrated in greater detail. The active region 112a comprises two MOSFETs that are connected in series. The MOSFETs may be NMOS or PMOS transistors. To provide the two MOSFETS, the active region 112a includes a drain 402, a gate 404, and a source 406 for the first MOS, and the source 406 (which is a shared source for both MOSFETs), a gate 408, and a drain 410 for the second MOS. The MOSFETs also include contacts 412 for the drain 402 and contacts 414 for the drain 410. It is understood that gates 404, 408 may also be associated with contacts, but are illustrated without contacts for purposes of clarity. Accordingly, references to the gates 404, 408 may also be references to contacts associated with the gates. Because the illustrated configuration of the active region 112a does not provide sufficient space between the gates 404, 408 for contacts, there may be insufficient room for a probe to directly measure the parasitic junction capacitance at the source 406.

With additional reference to FIG. 5, the active region 112a of FIGS. 1 and 4 is illustrated with contacts 412, 414, 500, and 502, as well as various parasitic junction capacitances 504, 506, 508, 510, and 512. The contacts provide connections to various components of the active region 112a as follows. The contact 412 is connected to the drain 402, the contact 500 is connected to the gate 404, the contact 502 is connected to the gate 408, and the contact 414 is connected to the drain 410.

The parasitic junction capacitances include the parasitic junction capacitance 504 (e.g., Cdb3) between the drain 402 and substrate 102, the parasitic junction capacitance 506 (e.g., Cdep3) between the gate 404 and substrate 102, the parasitic junction capacitance 508 (e.g., Csb2) between the source 406 and substrate 102, the parasitic junction capacitance 510 (e.g., Cdep4) between the gate 408 and substrate 102, and the parasitic junction capacitance 512 (e.g., Cdb4) between the drain 410 and substrate 102. While each of the parasitic junction capacitances 504, 506, 510, and 512 may be measured directly in the configuration of the active region 112a, the parasitic capacitance 508 (e.g., Csb2) may not be directly measurable due to the lack of space between the gates 404, 408.

Referring again to FIG. 1, the substrate 102 on which the structures 106 and 110 may be fabricated may use an elementary semiconductor such as crystal silicon, polycrystalline silicon, amorphous silicon, and germanium; a compound semiconductor such as silicon carbide and gallium arsenic; an alloy semiconductor such as SiGe, GaAsP, AlInAs, AlGaAs, and GaInP; or any combination thereof. Furthermore, the substrate 300 may be a semiconductor on insulator, such as silicon on insulator (SOI) or a thin film transistor (TFT). In some examples, the substrate 102 may include a doped epi layer or a buried layer. In other examples, the substrate 102 may comprise a compound semiconductor having a multiple silicon structure, or may include a multilayer compound semiconductor structure.

The MOS transistors used in the structures 106 and 110 may be fabricated as NMOS or PMOS transistors using a P-well or N-well structure, or may be fabricated directly onto or within the substrate 102.

The gate dielectric (not shown) in gates 204 and 208 of the structure 106 and the gate dielectric (not shown) in gates 404 and 408 of the structure 110 may be any suitable dielectric material. In the present embodiment, the dielectric material may have a relatively high level of integrity and exhibit relatively low current leakage. Examples of such dielectric materials include silicon oxide, silicon oxynitride, or a high k dielectric, such as hafnium oxide, zirconium oxide, aluminum oxide, a hafnium dioxide-alumina (HfO₂—Al₂O₃) alloy, or combinations thereof. The gate dielectric may be doped polycrystalline silicon with the same or different doping. In addition, spacers (not shown), that may be positioned on each side of a gate, may comprise a dielectric material such as silicon nitride, silicon oxide, silicon carbide, silicon oxynitride, or combinations thereof.

Silicide (not shown) may be formed on top of the sources, drains, and gates. The silicide may comprise such materials as nickel silicide, cobalt silicide, tungsten silicide, tantalum silicide, titanium silicide, platinum silicide, erbium silicide, palladium silicide, or combinations thereof.

Although the structures 106 and 110 are illustrated with transistors having a common source, it is understood that the transistors may be implemented with a common drain. Furthermore, the transistors may not be connected in series. Accordingly, the present disclosure may be applied to other circuit designs where the distance between two gates is too small for a probe to make contact.

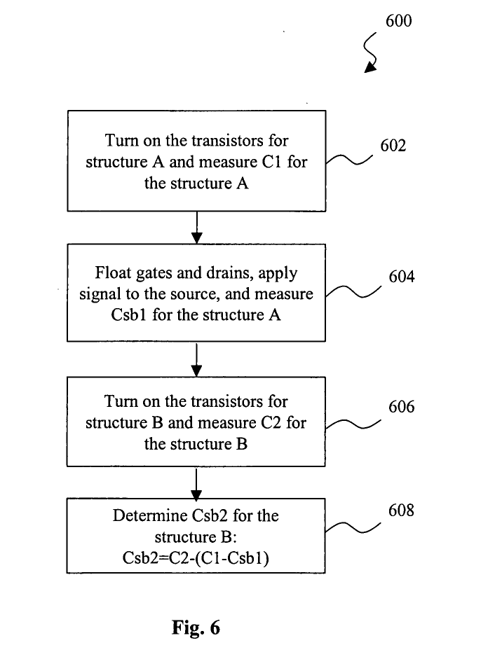

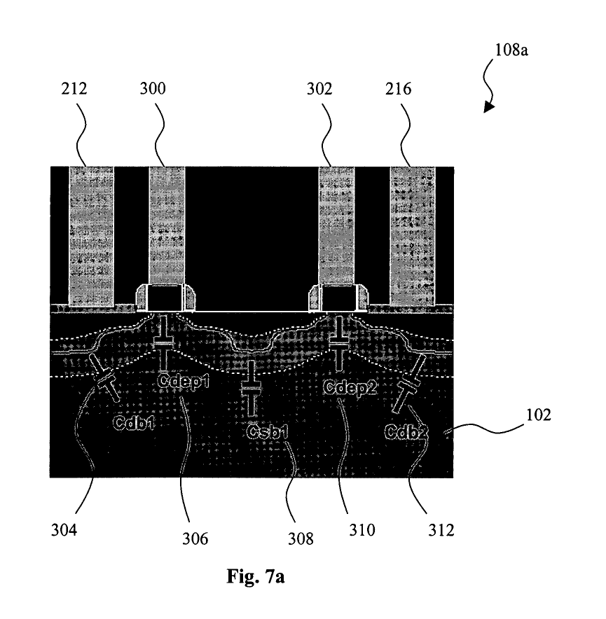

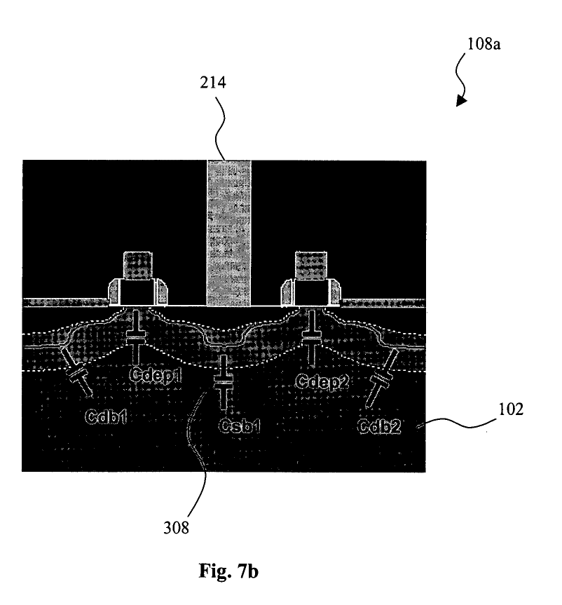

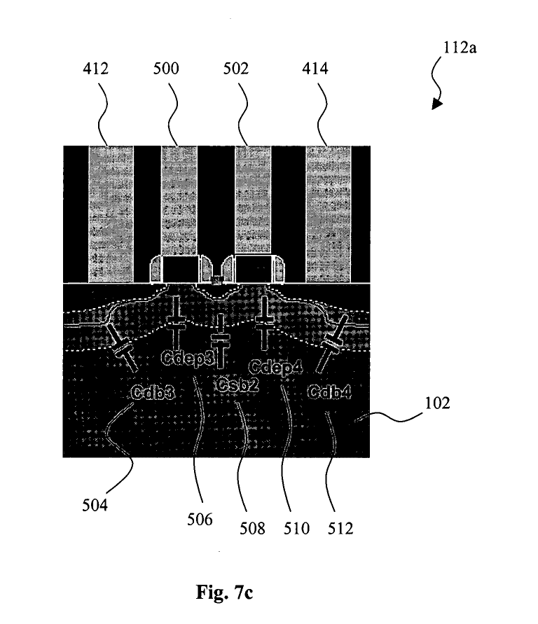

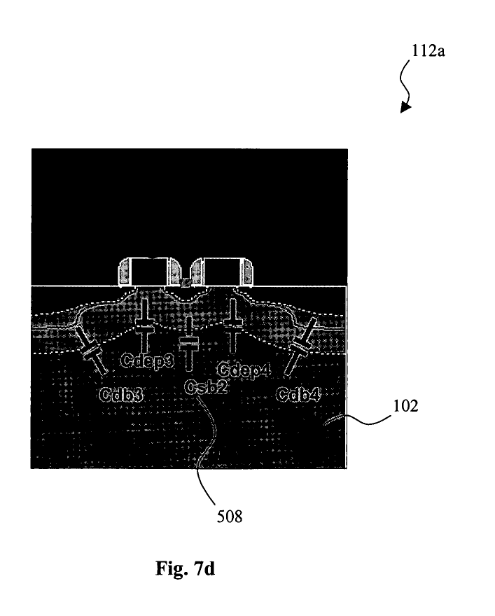

Referring now to FIG. 6 and with additional reference to FIGS. 7a-7d, in one embodiment, a method 600 may be used to determine parasitic junction capacitance in areas to which there is no direct access, such as the parasitic junction capacitance (e.g., Csb2) between the source 406 and substrate 102 of FIG. 4. For purposes of illustration, the method 600 is described in detail with respect to the active regions 108a and 112a of FIG. 1, but it is understood that the method 600 may be applied to the structures 106, 110, rather than single active regions.

With additional reference to FIG. 7a, the method 600 begins in step 602 when both MOS transistors (e.g., the transistors of the active region 108a) are turned on. This may be accomplished by applying a voltage through the gates 204 and 208 in the active region 108a via the contacts 300, 302, respectively. For example, the applied voltage to the gates 204, 208 may be 1 volt (V) if the transistors are NMOS transistors or −1 V if the transistors are PMOS transistors. The common source 206 is floating and the substrate 102 is grounded. A bias voltage of approximately 0 V plus a small signal may be applied to the drains 202, 210 through contacts 212 and 216. Accordingly, all five parasitic junction capacitances 304, 306, 308, 310, and 312 in the structure active region 108a are connected in parallel. This enables the total junction capacitance C1 between the substrate 102 and the drains 202, 210 to be calculated as:
C1=Cdb₁+Cdep₁+Csb₁+Cdep₂+Cdb₂ (Equation 1A)
In addition, both (202, 210) and (204, 208) are symmetry pairs, so
Cdb₁=Cdb₂ and Cdep₁=Cdep₂
Accordingly, Equation 1A may be rewritten as:
C₁₌2*(Cdb₁+Cdep₁)+Csb₁ (Equation 1B)

Accordingly, in the present example, by applying a small signal to both drains 202 and 210, the total junction capacitance C1 may be measured for the structure 106.

In step 604 and with additional reference to FIG. 7b, the gates 204 and 208, and the drains 202 and 210 are floated. The substrate 102 is grounded. A 0 V bias plus a small signal is applied to the common source 206 through the contact 214. This isolates the junction capacitance between the substrate 102 and the common source 206 to the parasitic junction capacitance 308 (Csb₁). Accordingly, by applying a small signal to the source 206, the junction capacitance Csb₁ between the source 206 and the substrate 102 may be measured for the active region 108a.

In step 606 and with additional reference to FIG. 5c, a measurement process similar to that of step 602 is applied to the active region 112a. In step 606, both MOS transistors (e.g., the transistors of the active region 112a) are turned on. This may be accomplished by applying a voltage through the gates 404 and 408 in the structure 110 (FIG. 1) via the contacts 500, 502, respectively. For example, the applied voltage to the gates 404, 408 may be 1 volt (V) if the transistors are NMOS transistors or −1 V if the transistors are PMOS transistors. The common source 406 is floating and the substrate 102 is grounded. A bias voltage of approximately 0 V plus a small signal may be applied to the drains 402, 410 through contacts 412 and 414. Accordingly, all five parasitic junction capacitances 504, 506, 508, 510, and 512 in the structure 110 (‘B’) are connected in parallel. This enables the total junction capacitance C2 between the substrate 102 and the drains 402, 410 to be calculated as:
C2=Cdb₃+Cdep₃+Csb₂+Cdep₄+Cdb₄ (Equation 2A)
In addition, both (402, 410) and (404, 408) are symmetry pairs, so
Cdb₃=Cdb₄ and Cdep₃=Cdep₄
Accordingly, Equation 2A may be rewritten as:
C2=2*(Cdb₃+Cdep₄)+Csb₂ (Equation 2B)

Accordingly, in the present example, by applying a small signal to both drains 402 and 410, the total junction capacitance C2 may be measured for the structure 110.

It is understood that, due to the symmetry of the structures 106 and 110, Cdb1=Cdb2=Cdb3=Cdb4 and Cdep1=Cdep2=Cdep3=Cdep4. In addition, Cdb may be defined as Cdb=Cdb1=Cdb2=Cdb3=Cdb4, and Cdep may be defined as Cdep=Cdep1=Cdep2=Cdep3=Cdep4. Accordingly, Equation 1B and Equation 2B may be rewritten, respectively, as:
C1=2*(Cdb+Cdep)+Csb1 (Equation 1C)
C2=2*(Cdb+Cdep)+Csb2 (Equation 2C)

In step 608 and with additional reference to FIG. 5d, the parasitic junction capacitance Csb₂ between the substrate 102 and source 406 in the active region 112a may be calculated from the measurements taken in the previous steps 602, 604, and 606 by using Equation IC and Equation 2C:
Csb₂=C2−(C1−Csb₁) (Equation 3)

Since the distance between the gates 404 and 408 is too small for a direct measurement of Csb2 to be made, Equation 3 may be used to determine the parasitic junction capacitance Csb₂.

With reference to FIGS. 1-5, junction capacitances Cdb and Cdep generally show negligible change when the distance between two neighboring gates is changed within a certain range. Accordingly, if the value of Cdb+Cdep is known for the structure 106, then the value of Cdb+Cdep for the structure 110 is also approximately known. Accordingly, if the total junction capacitance Ctotal=(2*(Cdb+Cdep)+Csb) and Csb can be measured, then the difference Ctotal−Csb=(2*(Cdb+Cdep)) is known and is a constant when the distance between the gates is changed.

The present disclosure has been described relative to a preferred embodiment. Improvements or modifications that become apparent to persons of ordinary skill in the art only after reading this disclosure are deemed within the spirit and scope of the application. It is understood that several modifications, changes and substitutions are intended in the foregoing disclosure and in some instances some features of the invention will be employed without a corresponding use of other features. For example, while the structures 106 and 110 are illustrated with MOSFETs, it is understood that other circuit configurations may be used. Furthermore, while the structures 106 and 110 are illustrated with transistors having a common source, it is understood that the transistors may be implemented with a common drain. In addition, the transistors may not be connected in series. Accordingly, the present disclosure may be applied to other circuit designs where the distance between two components is too small for a direct measurement to be made. Accordingly, it is appropriate that the appended claims be construed broadly and in a manner consistent with the scope of the invention.

1. A test structure formed on a semiconductor substrate and adapted to enable the calculation of parasitic junction capacitance, the test structure comprising:
a first structure formed on the substrate and having an array including at least one transistor pair, wherein the transistor pair includes first and second drains, first and second gates, and a first shared source positioned between the first and second gates, wherein the first and second gates are spaced to enable direct measurement of a first capacitance associated with the first shared source; and
a second structure formed on the substrate and having an array including at least one transistor pair, wherein the transistor pair includes third and fourth drains, third and fourth gates, and a second shared source positioned between the third and fourth gates, and wherein the third and fourth gates are spaced to prevent direct measurement of a second capacitance associated with the second shared source.

2. The test structure of claim 1 wherein the semiconductor substrate comprises an elementary semiconductor selected from the group consisting of crystal silicon, polycrystalline silicon, amorphous silicon, and germanium.

3. The test structure of claim 1 wherein the semiconductor substrate comprises a compound semiconductor selected from the group consisting of silicon carbide and gallium arsenic.

4. The test structure of claim 1 wherein the semiconductor substrate comprises an alloy semiconductor selected from the group consisting of SiGe, GaAsP, AlInAs, AlGaAs, and GaInP.

5. The test structure of claim 1 wherein the semiconductor substrate comprises a semiconductor on insulator construction.

6. The test structure of claim 1 wherein each transistor of the first and second structures are metal oxide semiconductor (MOS) transistors.

7. The test structure of claim 6 wherein the MOS transistors are negative channel MOS transistors.

8. The test structure of claim 6 wherein the MOS transistors are positive channel MOS transistors.

9. The test structure of claim 1 wherein each pair of transistors is connected in series.

10. A test structure formed on a semiconductor substrate and adapted to enable the calculation of parasitic junction capacitance, the test structure comprising:
a first structure formed on the substrate and having an array including at least one transistor pair, wherein each transistor pair includes first and second sources, first and second gates, and a first shared drain positioned between the first and second gates, wherein the first and second gates are spaced to enable direct measurement of a first capacitance associated with the first shared drain; and
a second structure formed on the substrate and having an array including at least one transistor pair, wherein each transistor pair includes third and fourth sources, third and fourth gates, and a second shared drain positioned between the third and fourth gates, and wherein the third and fourth gates are spaced to prevent direct measurement of a second capacitance associated with the second shared drain.

11. A method for calculating a parasitic junction capacitance of a second transistor pair based on capacitance values of a first transistor pair and capacitance values of the second transistor pair, wherein the parasitic junction capacitance of the second transistor pair cannot be measured directly, the method comprising:
measuring a total junction capacitance of the first transistor pair;
measuring a parasitic junction capacitance of the first transistor pair;
measuring a total junction capacitance of the second transistor pair;
applying an alternating current (AC) signal to a common source or common drain of the first transistor pair and measuring a total junction capacitance at the common source or common drain for the first transistor pair;
applying an AC signal to the common source or common drain of the first transistor pair and measuring a parasitic junction capacitance at the common source or common drain for the first transistor pair; and
applying an AC signal to a common source or common drain of the second transistor pair and measuring a total junction capacitance at the common source or common drain for the second transistor pair.

12. The method of claim 11 further comprising:
turning on the transistors of the first transistor pair prior to measuring the total junction capacitance of the first transistor pair;
turning on the transistors of the second transistor pair prior to measuring the total junction capacitance of the second transistor pair; and
floating at least one gate associated with the first transistor pair, floating a drain associated with the first transistor pair if the source is common, and floating a source associated with the first transistor pair if the drain is common, wherein the floating is performed prior to measuring the parasitic junction capacitance of the first transistor pair.

13. A method for calculating a parasitic junction capacitance in a test structure, wherein the test structure comprises a first transistor pair having a first shared source associated with a parasitic junction capacitance (Csb1), and first and second gates spaced to enable direct measurement of Csb1, and wherein the test structure also comprises a second transistor pair having a second shared source associated with a parasitic junction capacitance (Csb2), and third and fourth gates spaced to prevent direct measurement of Csb2, the method comprising:
measuring a total junction capacitance (C1) of the first transistor pair;
measuring Csb1 at the shared source of the first transistor pair;
measuring a total junction capacitance (C2) of the second transistor pair; and
determining Csb2 using C1, C2, and Csb1.

14. The method of claim 13 further comprising:
turning on the transistors of the first transistor pair prior to measuring the C1;
applying a signal to the first shared source prior to measuring the Csb1; and
turning on the transistors of the second transistor pair prior to measuring C2.

15. The method of claim 14 further comprising, prior to applying the signal to the first shared source, floating the first and second gates and floating first and second drains associated with the first transistor pair.

16. The method of claim 13 wherein Csb2=C2−(C1−Csb 1).

17. A test system for determining a parasitic capacitance that cannot be directly measured, the system comprising:
a first transistor pair having gates and a first shared source or a shared drain for the two transistors of the first transistor pair, wherein the gates are spaced to enable direct measurement of a parasitic capacitance (Csb1) associated with the first shared source or shared drain;
a second transistor pair having gates and a second shared source or a shared drain for the two transistors of the second transistor pair, wherein the gates are spaced to prevent direct measurement of a parasitic capacitance (Csb2) associated with the second shared source or shared drain; and
testing means for measuring a total junction capacitance (C1) of the first transistor pair, for measuring Csb1 at the first shared source or shared drain, and for measuring a total junction capacitance (C2) of the second transistor pair, wherein Csb2 is determined using C1, C2, and Csb1.

18. The test system of claim 17 further comprising electrical means for connecting regions associated with the first and second transistor pairs to a voltage source or to ground.
